(19) United States
(12) Patent Application Publication
(10) Pub. No.: US 2026/0100628 A1
(43) Pub. Date: Apr. 9, 2026

(54) REVERSIBLE COOLING LOOP USING MAGNETOHYDRODYNAMIC PUMP FOR SYSTEMS WITH VARIABLE HEAT DISTRIBUTION

(71) Applicant: L3Harris Technologies, Inc., Melbourne, FL (US)

(72) Inventors: Hong LIU, Chino Hills, CA (US); Deepanjan MITRA, Irvine, CA (US); Lixin TANG, Irvine, CA (US)

(21) Appl. No.: 18/905,206

(22) Filed: Oct. 3, 2024

(51) Int. Cl. H02K 44/04; H05K 7/20

(52) U.S. Cl. CPC H02K 44/04; H05K 7/20254; H05K 7/20327; H05K 7/20927; H05K 7/20945

(57) ABSTRACT

An apparatus comprises: electric circuits including a first circuit and a second circuit to operate in multiple modes including a first mode in which the first circuit dissipates more heat than the second circuit and in a second mode in which the second circuit dissipates more heat; and a coolant loop along which the first circuit and the second circuit are thermally coupled at spaced-apart locations, wherein the coolant loop includes a reversible magnetohydrodynamic (MHD) pump to pump a cold liquid metal through the coolant loop in reversible coolant-flow directions responsive to reversible current directions of a current applied to the MHD pump, such that when the first mode is active, the cold liquid metal initially encounters the first circuit and then encounters the second circuit, and when the second mode is active, the cold liquid metal initially encounters the second circuit and then encounters the first circuit.

### TECHNICAL FIELD

The present disclosure relates to power circuit cooling systems that use magnetohydrodynamic (MHD) pumps.

### BACKGROUND

A direct current (DC)-to-DC (DC-DC) converter includes switching transistors that may be controlled to operate in either a Buck mode or a Boost mode. The DC-DC converter can alternate/switch between the two modes. When the DC-DC converter operates in the different modes, the switching transistors experience imbalanced power dissipation across the different modes. For example, when the Buck mode is active, a first switching transistor experiences more power loss (i.e., dissipates more heat) and runs at a higher temperature (i.e., runs hotter) than a second switching transistor. Conversely, when the Boost mode is active, the second switching transistor dissipates more heat and thus runs hotter than first switching transistor. A conventional cooling system applies equivalent cooling to the first and second switching transistors that dissipate the unequal heat. This results in a higher junction temperature of the first or second switching transistor depending on which mode is active, in which case the cooling becomes a bottleneck for the DC-DC converter, limiting its maximum power and power density.

### BRIEF DESCRIPTION OF THE DRAWINGS

FIG. 1 is a circuit diagram of an example power circuit to be cooled by a reversible liquid metal coolant apparatus.

FIG. 2 shows a portion of an example reversible liquid metal coolant apparatus that cools the power circuit when the power circuit operates in a first mode (mode 1).

FIG. 3 shows the reversible liquid metal coolant apparatus when the power circuit operates in a second mode (mode 2).

FIG. 4 is a diagram of an example magnetohydrodynamic (MHD) pump for an embodiment E1.

FIG. 5 shows operation of the MHD pump for embodiment E1 when operating in mode 1.

FIG. 6 shows operation of the MHD pump for embodiment E1 when operating in mode 2.

FIG. 7 is a diagram of an example MHD pump for an embodiment E2.

FIG. 8 shows the MHD pump for embodiment E2 operating in mode 1.

FIG. 9 shows the MHD pump for embodiment E2 operating in mode 2.

FIG. 10 is a table that shows example mappings between operating modes, a transition mode, and corresponding switch states for switches of a programmable switch network for embodiment E2.

FIG. 11 is a diagram of a variation of the MHD pump for embodiment E2.

FIG. 12 shows waveforms for a supply current, an MHD current, and a speed of liquid metal flow for embodiment E2.

FIG. 13 shows an example liquid metal coolant apparatus that uses an MHD pump and a liquid-to-air heat exchanger (L2AHE) while operating in mode 1.

FIG. 14 shows the liquid metal coolant apparatus of FIG. 13 operating in mode 2.

FIG. 15 shows an example liquid metal coolant apparatus using an MHD pump and a liquid-to-liquid heat exchanger (L2LHE) for embodiment M1 operating in mode 1.

FIG. 16 shows the liquid metal coolant apparatus of embodiment M1 operating in mode 2.

FIG. 17 shows an example liquid metal coolant apparatus using an MHD pump and an L2LHE for embodiment M2 operating in mode 1.

FIG. 18 shows the liquid metal coolant apparatus of embodiment M2 operating in mode 2.

FIG. 19 is a table that shows example mappings between operating modes, a transition mode, and corresponding switch states for embodiments M1 and M2.

FIG. 20 is a flowchart of an example method of cooling an electric circuit using an MHD pump that circulates liquid metal through a coolant loop.

FIG. 21 is a flowchart on an example method of cooling an electric circuit using an MHD and multiple flow loops.

FIG. 22 is a flowchart on an example method of operating an MHD pump.

FIG. 23 is a block diagram of an example controller configured to perform operations described herein.

### DESCRIPTION OF EXAMPLE EMBODIMENTS

### Overview

In an embodiment, an apparatus comprises: electric circuits including a first circuit and a second circuit configured to operate in multiple modes including a first mode in which the first circuit dissipates more heat than the second circuit and in a second mode in which the second circuit dissipates more heat than the first circuit; and a coolant loop along which the first circuit and the second circuit are thermally coupled at spaced-apart locations, wherein the coolant loop includes a reversible magnetohydrodynamic (MHD) pump to pump a cold liquid metal through the coolant loop in reversible coolant-flow directions responsive to reversible current directions of a current applied to the MHD pump, such that when the first mode is active, the cold liquid metal initially encounters and cools the first circuit and then encounters and cools the second circuit, and when the second mode is active, the cold liquid metal initially encounters and cools the second circuit and then encounters and cools the first circuit.

In another embodiment, an apparatus comprises: a coolant loop to cool a power circuit thermally coupled to the coolant loop, the coolant loop including a heat exchanger to cool a hot liquid metal to a cold liquid metal, and an MHD pump, responsive to reversible current directions of a current applied to the MHD pump, to pump the cold liquid metal in reversible coolant-flow directions each configured to cause the cold liquid metal to flow by and cool the power circuit, which warms the cold liquid metal to the hot liquid metal, and then to cause the hot liquid metal to flow to the heat exchanger; and a cooling loop to circulate a cooling liquid in a cooling-liquid flow direction through the heat exchanger to cool the hot liquid metal in the heat exchanger, wherein the reversible coolant-flow directions and the cooling-liquid flow direction are configured to establish a counterflow of the hot liquid metal and the cooling liquid through the heat exchanger.

In yet another embodiment, an apparatus comprises: a coolant conduit to which an electric circuit is thermally coupled; an MHD pump to pump a cold liquid metal that is electrically conductive through the coolant conduit responsive to a current and a magnetic field that are applied across the MHD pump; a magnet to generate the magnetic field; a programmable power switch network coupled to the MHD pump; a current source to supply the current to the programmable power switch network; and a controller to program the programmable power switch network into alternate power-switch configurations configured to apply the current from the current source across the MHD pump in alternate current directions, which compel the MHD pump to pump the cold liquid metal through the coolant conduit in alternate coolant-flow directions past the electric circuit to cool the electric circuit.

### Example Embodiments

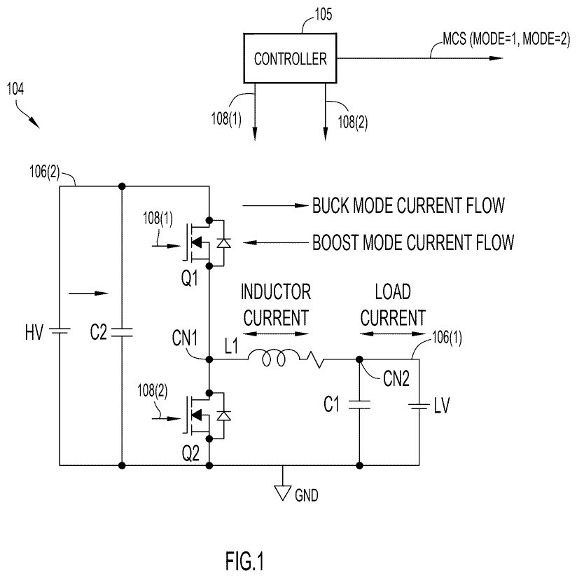

FIG. 1 is a circuit diagram of an example power circuit 104 (also referred to as an “electric circuit”) to be cooled by a reversible liquid metal coolant apparatus, described below. Power circuit 104 includes a non-isolated bi-directional DC-DC converter, which may be used in a range of power systems, including maritime power systems, as an interface between different DC power nets, and which may be used for impedance control of different power stages, for example. Power circuit 104 operates in a first direction to generate a DC voltage LV across a voltage rail 106(1) and ground (GND) based on a DC voltage HV that is applied across a voltage rail 106(2) and ground. Power circuit 104 also operates in a reverse direction to generate DC voltage HV from DC voltage LV. Power circuit 104 is considered non-isolated because the opposing ends of the power circuit (e.g., LV and HV) are not isolated. In the example of FIG. 1, power circuit 104 is configured as a Buck or Boost converter, which may operate selectively in different (e.g., reversible) modes, including a Boost converter mode (i.e., Boost mode) or a Buck converter mode (i.e., Buck mode).

Power circuit 104 includes a first switching transistor Q1 (referred to as “Q1”) and a second switching transistor Q2 both operated under control of a controller 105. Q1 has a source-drain path connected to voltage rail 106(2) and an intermediate node CN1, and a gate to receive a switching signal 108(1) generated by controller 105 to alternately turn on (i.e., switch on) and turn off (i.e., switch off) the source-drain current path. Q2 has a source-drain path connected to ground and to intermediate node CN1 such that the source-drain paths of Q1 and Q2 are connected in series between voltage rail 106(2) and ground, and a gate to receive a switching signal 108(2) generated by controller 105 to turn on and turn off Q2. Q1, Q2 may each be a Silicon (Si) Carbide (C) (SiC) MOSFET or other type of transistor. In an example, switching signals 108(1), 108(2) may comprise pulse width modulation (PWM) signals. The configuration of switching signals 108(1) and 108(2) (e.g., switching frequency, pulse width, phase, and so on) determines whether power circuit 104 operates in the Buck mode or the Boost mode. Power circuit 104 includes a capacitor C2 coupled to and across voltage rail 106(2) and ground. Power circuit 104 also includes an inductor L1 coupled to node CN1 and a node CN2, and a capacitor C1 coupled to node N2 and ground. Power circuit 104 can have multiple sets of Q1, Q2 and L1 to scale up the power level of the converters, and interleaved gate signals can be used to reduce the output voltage ripples.

Controller 105 generates and configures switching signals 108(1) and 108(2) to control whether power circuit 104 operates in/implements the Buck mode or the Boost mode. In other words, controller 105 sets the operating mode of power circuit 104 to the Buck mode or the Boost mode through switching signals 108(1) and 108(2). Controller 105 also generates a mode control signal MCS indicative of the mode, and which may be used by other circuits, not shown. In the Buck mode (i.e., when the Buck mode is active), power circuit 104 reduces an input voltage to produce an output voltage. In the Buck mode, an inductor current and a load current flow in a first current direction. In contrast, in the Boost mode (i.e., when the Boost mode is active), power circuit 104 boosts the input voltage to produce the output voltage. In the Boost mode, the inductor current and the load current of power circuit 104 flow in a second current direction that is opposite to (i.e., a reverse of) the first current direction.

When power circuit 104 operates in the different modes, switches Q1, Q2 have imbalanced power dissipation across the different modes. For example, when the Buck mode is active, Q1 experiences more power loss (i.e., dissipates more heat). In the Buck mode, Q1 represents a high-power circuit that dissipates more heat than Q2, which represents a low-power circuit. Conversely, when the Boost mode is active, Q2 dissipates more heat. In the Boost mode, Q2 becomes the high-power circuit and Q1 becomes the low-power circuit. Were equivalent cooling to be applied to Q1 and Q2 in both modes, the unequal heat dissipation would result in one of Q1 or Q2 growing increasingly hotter than the other one of Q1 or Q2 depending on the mode, in which case cooling becomes a bottleneck for power circuit 104, limiting the maximum power and power density.

Accordingly, embodiments presented herein include reversible liquid metal coolant apparatuses that employ dynamically controlled liquid metal coolant to more effectively cool Q1 and Q2 across the different modes. More specifically, the reversible liquid metal coolant apparatuses employ magnetohydrodynamic (MHD) pumps to reverse the flow direction of the liquid metal in coolant loops to better-cool variable heat distributions along the coolant loops.

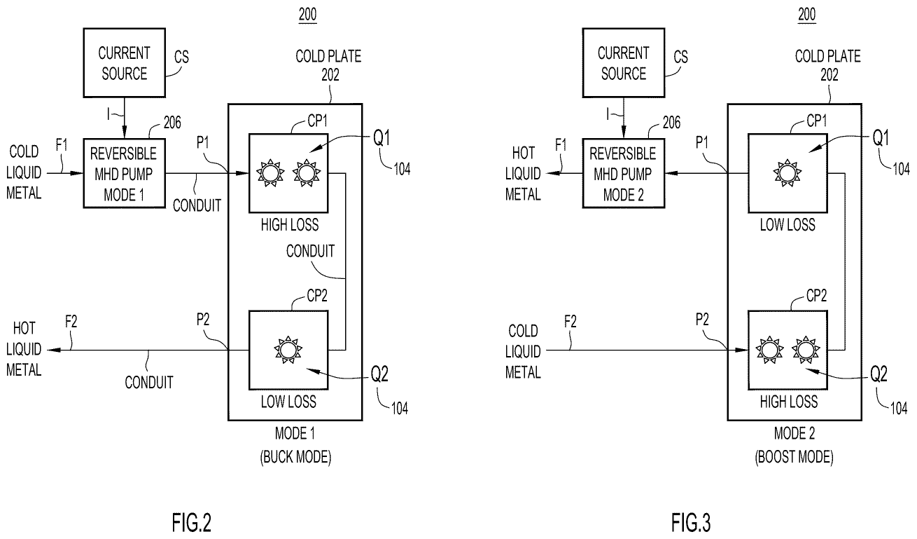

FIGS. 2 and 3 present a portion of a reversible liquid metal coolant apparatus, which is useful for describing concepts presented herein. In the ensuing description, the Buck mode and the Boost mode are respectively referred to as “mode 1” and “mode 2.”

FIG. 2 shows a portion of an example reversible liquid metal coolant apparatus 200 that cools power circuit 104 when the power circuit operates in mode 1 (e.g., the Buck mode) in which Q1 dissipates more heat than Q2. Reversible liquid metal coolant apparatus 200 includes a conduit (or contiguous conduit segments) that forms a liquid metal coolant loop (also referred to simply as a “coolant loop”) to convey or carry an electrically conductive liquid metal coolant (also referred to simply as a “liquid metal”) between opposing open ends or ports F1 and F2 of the conduit/coolant loop, to cool Q1 and Q2. In FIG. 2 (and other figures presented herein), the coolant loop is represented as a series of arrows connecting (and passing through) the components of the reversible liquid metal coolant apparatus. Directions of the arrows represent directions of fluid flow.

Reversible liquid metal coolant apparatus 200 includes a cold plate 202 through which a conduit segment (also referred to simply as a “segment”) of the coolant loop extends between spaced-apart ports P1 and P2 of the cold plate. Ports P1 and P2 also represent first and second open ends of that segment, respectively. Q1, Q2 are respectively mounted to cold patches CP1, CP2 of cold plate 202 positioned nearest/adjacent to ports P1, P2, respectively. In this configuration, Q1, Q2 are thermally coupled to spaced-apart locations along the coolant loop.

Reversible liquid metal coolant apparatus 200 further includes an MHD pump 206 connected in-line and in fluid communication with the coolant loop (e.g., between ports F1 and P1) such that the liquid metal can flow through the MHD pump. Reversible liquid metal coolant apparatus 200 also includes a current source CS to apply a current I to the MHD pump, and to control a current direction of the current based on the mode of power circuit 104. MHD pump 206 circulates or pumps the liquid metal through the coolant loop (including cold plate 202) in a coolant-flow direction responsive to the current direction (and a magnetic field direction applied to the MHD pump, not shown).

In an example, power circuit 104 may serve as current source CS. When power circuit 104 serves as current source CS, current I may be tapped from (i.e., be based on) the inductor current or the load current which flows through the power circuit. In that case, current I automatically reverses current direction when power circuit 104 reverses modes. Additionally, a level of current I varies in correspondence with a level of the heat dissipated by Q1 and Q2.

For mode 1, port F1 receives the liquid metal in a cold state (referred to as the “cold liquid metal”), and current source CS applies current I to MHD pump 206 in the first current direction corresponding to mode 1 (as described above in connection with FIG. 1). In response to the first current direction, MHD pump 206 pumps the cold liquid metal in a first coolant-flow direction (e.g., clockwise) through the coolant loop from port F1 to port P1 near Q1. The cold liquid metal flows from port P1 to port P2 such that the cold liquid metal initially encounters (i.e., flows by or past) and cools Q1, and then (i.e., subsequently) encounters and cools Q2. As the cold liquid metal flows past Q1 and then Q2, the cold liquid metal warms/transitions to a hot liquid metal. The hot liquid metal flows from port P2 near Q2 to port F2.

FIG. 3 shows reversible liquid metal coolant apparatus 200 when power circuit 104 operates in mode 2 (e.g., the Boost mode). For mode 2, port P2 receives the cold liquid metal, and current source CS applies current I to MHD pump 206 in the second current direction corresponding to mode 2. MHD pump 206 pumps the cold liquid metal in a second coolant-flow direction (e.g., counterclockwise) through the coolant loop that is opposite to (i.e., reverse of) the first coolant-flow direction. The liquid metal flows from port F2 to port P2 near Q2, such that the cold liquid metal initially encounters and cools Q2, and then encounters and cools Q1. As the cold liquid metal flows past Q2 and then Q1, the cold liquid metal warms to the hot metal coolant. The hot metal coolant flows from port P1 near Q1 to port F1.

In summary, when power circuit 104 operates in multiple (e.g., reversible) modes M1 and M2, current source CS applies current I to MHD pump 206 in reversible current directions corresponding to the multiple modes. The reversible current directions include the first current direction and the second current direction for modes M1 and M2, which cause (i.e., compels) MHD pump 206 to pump the cold liquid metal in reversible coolant-flow directions (also referred to as “alternate coolant-flow directions”) that include the first coolant-flow direction to cool Q1 initially, and the second coolant-flow direction to cool Q2 initially, respectively. Therefore, MHD pump 206 pumps the cold liquid metal in the reversible coolant-flow directions to ensure that the cold liquid metal initially encounters whichever of Q1 and Q2 dissipates more heat in whichever of the multiple modes M1 and M2 is active. Such operation is common across the embodiments.

In an arrangement that taps current I from power circuit 104 (e.g., from the inductor current or the load current), the current direction, and correspondingly the coolant-flow direction, automatically reverse with the mode. Moreover, a speed or flow rate at which MHD pump 206 pumps the cold metal coolant increases and decreases as the level of current I increases (as heat dissipation increases) and decreases (as heat dissipation decreases), which results in self-regulated cooling of power circuit 104.

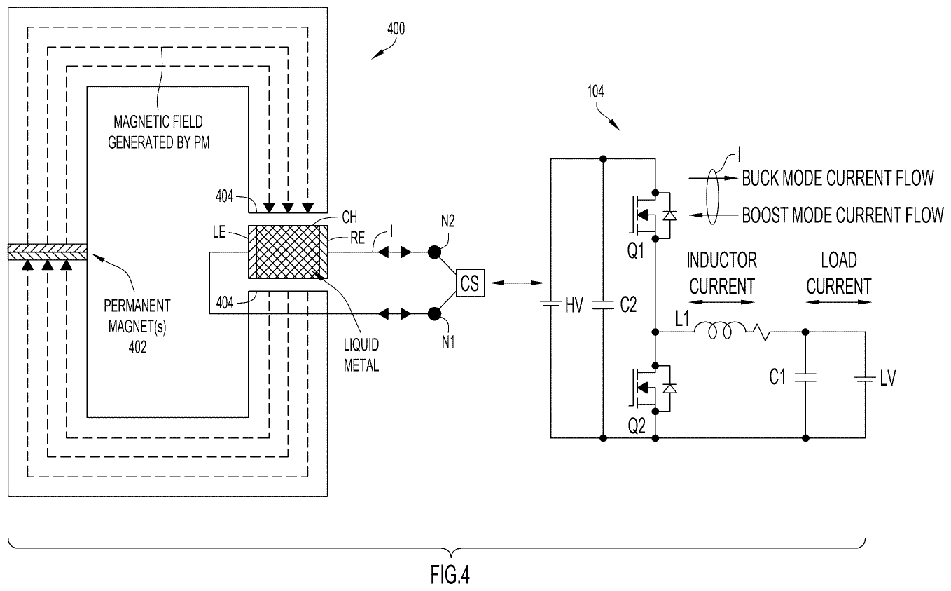

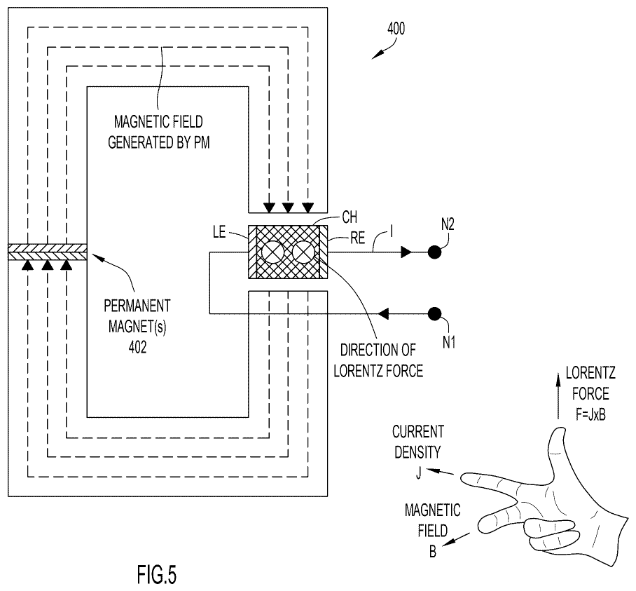

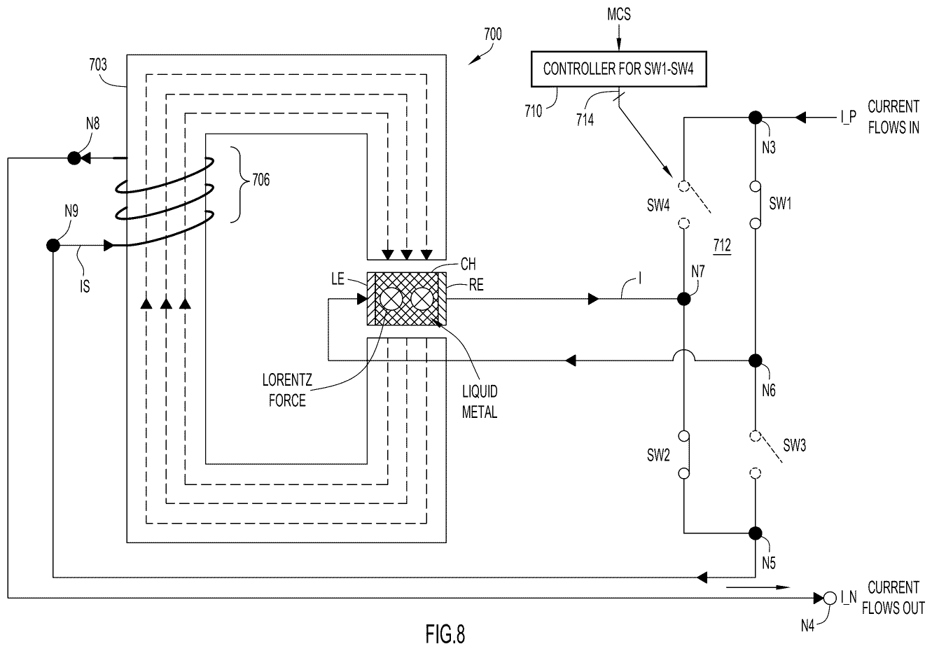

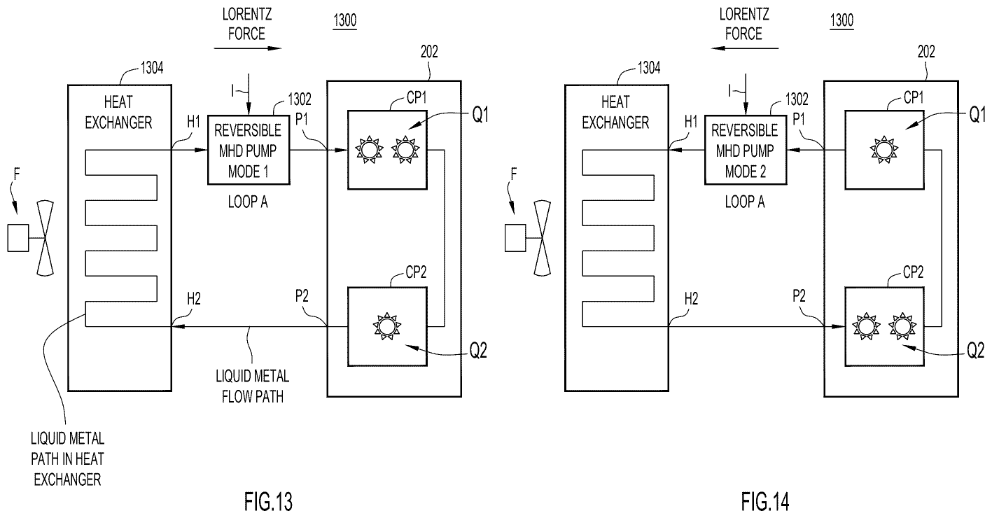

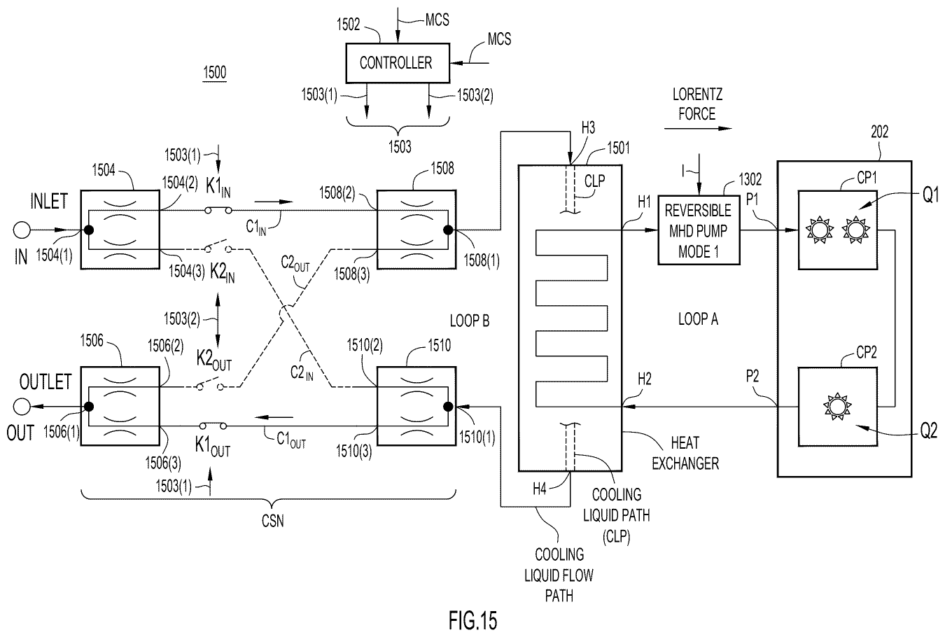

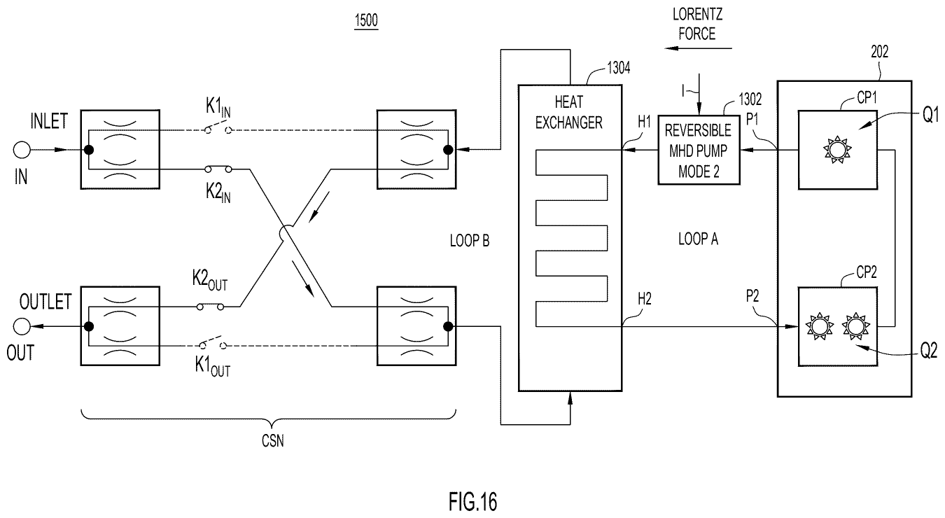

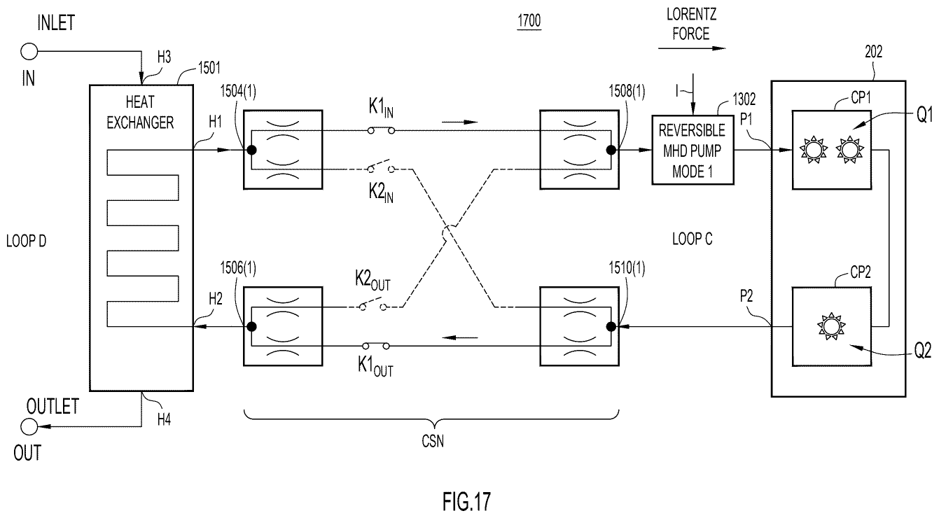

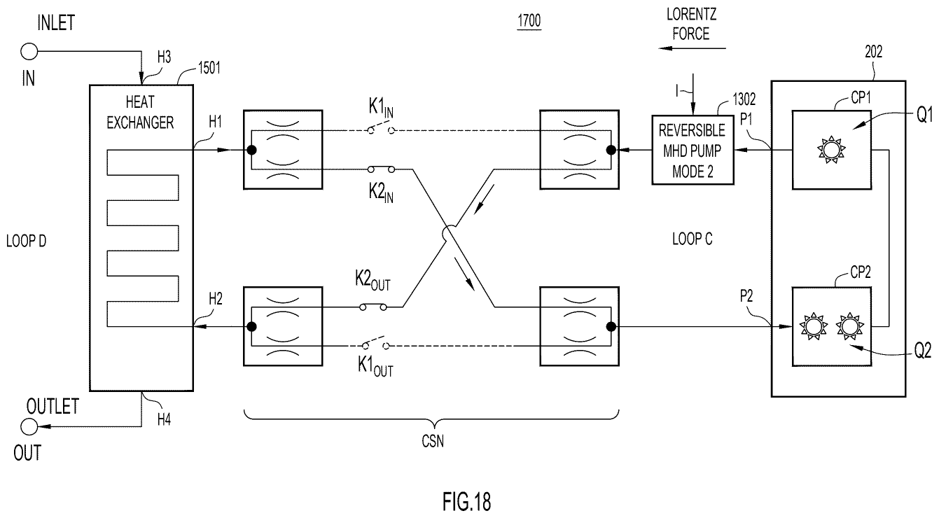

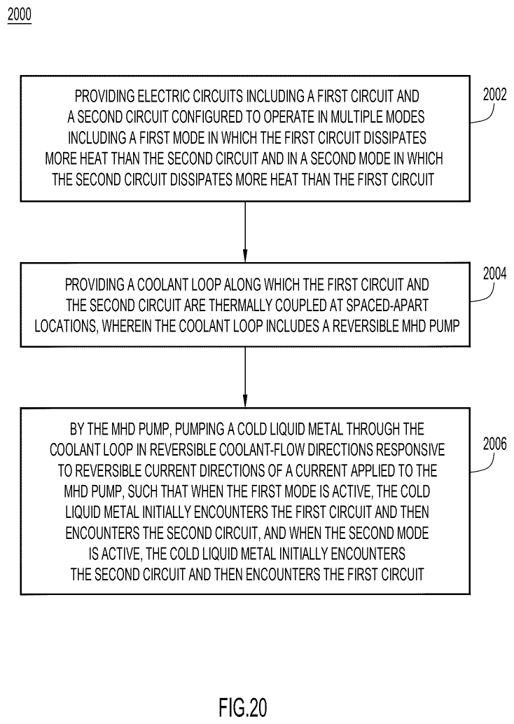

Further embodiments are described below. The embodiments include, but are not limited to, the following:
a. An electrical embodiment E1 (where “E” represents electrical) directed to the structure of the MHD pump. FIGS. 4-6.
b. An electrical embodiment E2 directed the structure of the MHD pump, including a variation of embodiment E2. FIGS. 7-9 and 11.
c. A mechanical embodiment M3 directed to a fluid loop that includes the MHD pump with a liquid-to-air heat exchanger (L2AHE). FIGS. 13 and 14.
d. A mechanical embodiment M1 (where “M” represents mechanical) directed to multiple fluid loops that employ the MHD pump and a liquid-to-liquid heat exchanger (L2LHE). FIGS. 15 and 16.
e. A mechanical embodiment M2 directed to multiple fluid loops that employ the MHD pump and the L2LHE. FIGS. 17 and 18.
f. Method embodiments. FIGS. 20-23.

Various combinations of the above-listed embodiments are possible. For example, embodiment M1 may be used with embodiments E1 and E2, embodiment M2 may be used with embodiments E1 and E2, and embodiment M3 may be used with embodiments E1 and E2.

FIG. 4 is a diagram of an example MHD pump 400 (corresponding to MHD pump 206 of FIGS. 2 and 3) according to embodiment E1. Embodiment E1 uses the load current (or the inductor current) with unipolar field excitation, as described below. MHD pump 400 includes a permanent magnet (PM) 402 (shown in cross-section) that is C-shaped to have opposing ends 404 that are vertically spaced-apart to define a vertical gap therebetween. MHD pump 400 includes a channel CH (shown in cross-section) clamped in the gap by/between opposing ends 404. Channel CH is in fluid communication with the coolant loop described above. Therefore, the liquid metal can flow through the channel. Channel CH may be made of an isolation material to isolate the liquid metal from other parts. Channel CH has vertically spaced-apart top and bottom sides adjacent to opposing ends 404, and horizontally spaced-apart left and right sides that collectively define a rectangular cross-section of the channel. The channel has a length that extends normally to the plane of the figure. The left side and the right side of channel CH include a left electrode LE and a right electrode RE connected to a node N1 and a node N2 of MHD pump 400, respectively.

Permanent magnet 402 generates a magnetic field that flows across the gap/channel CH in a downward vertical direction. Current source CS connected to nodes N1, N2 applies current I (also referred to as an “MHD current”) to left and right electrodes LE, RE through the nodes, such that the current flows across channel CH in a horizontal direction (which is referred to as an “MHD current path”). In an example, power circuit 104 may serve as the current source, in which case current I may include the load current or the inductor current tapped from the power circuit, as described above.

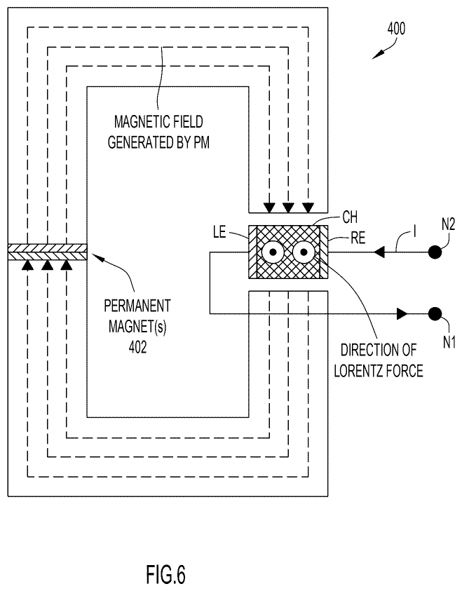

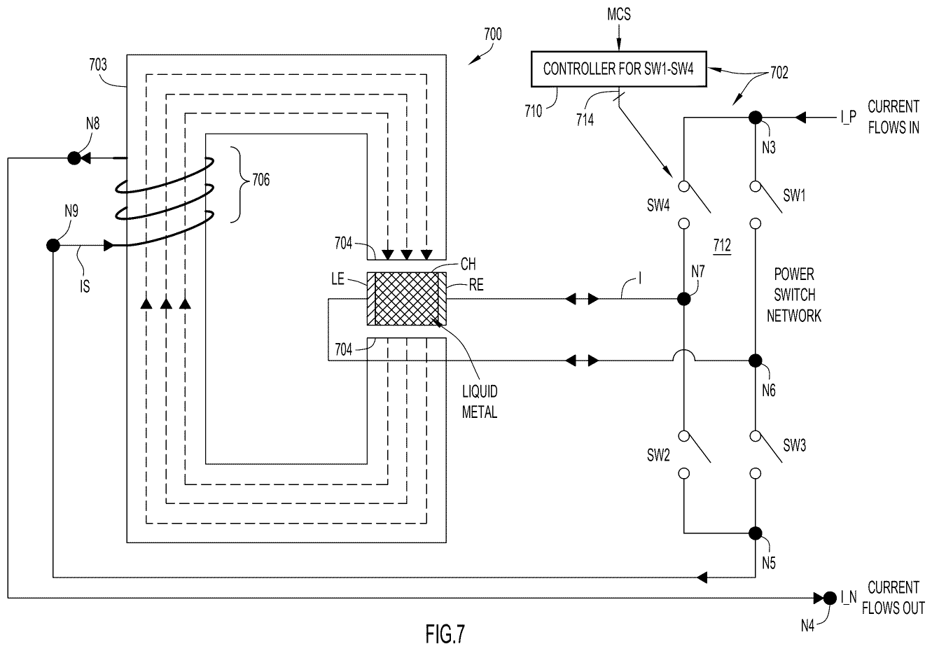

Together, the magnetic field and the current I applied to the liquid metal contained in channel CH induce a Lorentz force on the liquid metal. The Lorentz force has a direction based on the current direction (e.g., flowing left or right) and the direction of the magnetic field (which is downward in FIG. 4), according to the Right Hand Law. The Lorentz force pumps the liquid metal through the channel (i.e., along the length of the channel) in a coolant-flow direction that is normal to the plane of the figure, according to the Right Hand Law, as illustrated in FIGS. 5 and 6 described below.

FIG. 5 shows operation of MHD pump 400 for embodiment E1 in mode 1. In mode 1, the current source applies current I to node N1 in the first current direction (i.e., node N1 receives current I) such that current I flows left-to-right across channel CH. According to the Right Hand Law, the Lorentz force is directed normally into the plane of the figure. Thus, MHD pump 400 pumps the liquid metal in that direction.

FIG. 6 shows operation of MHD pump 400 for embodiment E1 in mode 2. In mode 2, the current source applies current I to node N2 in the second current direction (i.e., node N2 receives current I). In the example, of FIG. 6, current I flows left-to-right across channel CH. According to the Right Hand Law, the Lorentz force is directed normally out of the plane of the figure. Thus, MHD pump 400 pumps the metal liquid coolant in that direction.

FIG. 7 is a diagram of an example MHD pump 700 (corresponding to MHD pump 206 of FIGS. 2 and 3) and an example current control circuit 702 coupled to the MHD pump, according to embodiment E2. MHD pump 700 includes an electromagnet 703 (shown in cross-section) that has a C-shaped magnetic core, similar to the shape of permanent magnet 402. The C-shaped magnetic core includes opposing ends 704 that define a gap between the opposing ends and that clamp channel CH (shown in cross-section) in the gap. Electromagnet 703 includes a field winding 706 (also referred to simply as a “winding”) that carries a winding current IS to induce a magnetic field in the magnetic core that flows vertically downward through channel CH, similar to the arrangement of MHD pump 400.

Current control circuit 702 includes a controller 710 and a power switch network (PSN) 712. Controller 710 receives mode control signal MCS. PSN 712 supplies winding current IS to field winding 706 and current I (i.e., the MHD current) to channel CH under control of switch control signals 714 generated by controller 710 responsive to mode control signal MCS. Current control circuit 702 includes nodes N3 and N4 connected to a current source (not shown), which supplies a current I_P (also referred to as a “supply current”) into node N3, and receives a return current I_N through N4. The current source may include any know or hereafter developed current source. The flow rate of the liquid metal pumped by MHD pump 700 may be controlled by current regulation of current I_P.

PSN 712 includes switches SW1-SW4 (which may also be referred to as “current switches” and “power switches”), connected to node N3 and a node N5. Switches SW1-SW4 are individually controlled to open (i.e., turn off) or close (i.e., turn on) in responsive to respective ones of switch control signals 714. Switches SW1-SW4 are electrical switches with current forward blocking and current handling capability, such as power semiconductor switches (e.g., FET switches) or contactor switches, all of which allow unidirectional electric current flow. Switches SW1 and SW3 are connected in series with each other from node N3 to node N5, and connected to each other at an intermediate node N6 that is connected to left electrode LE of channel CH. Switches SW4 and SW2 are connected in series with each other from node N3 to node N5, and connected to each other at an intermediate node N7 that is also connected to right electrode RE of channel CH. Field winding 706 includes nodes N8 and N9 at opposing ends of the field winding and respectively connected to nodes N4 and N5, which apply winding current IS to the field winding. Thus, nodes N4 and N5 are connected to each other through field winding 706.

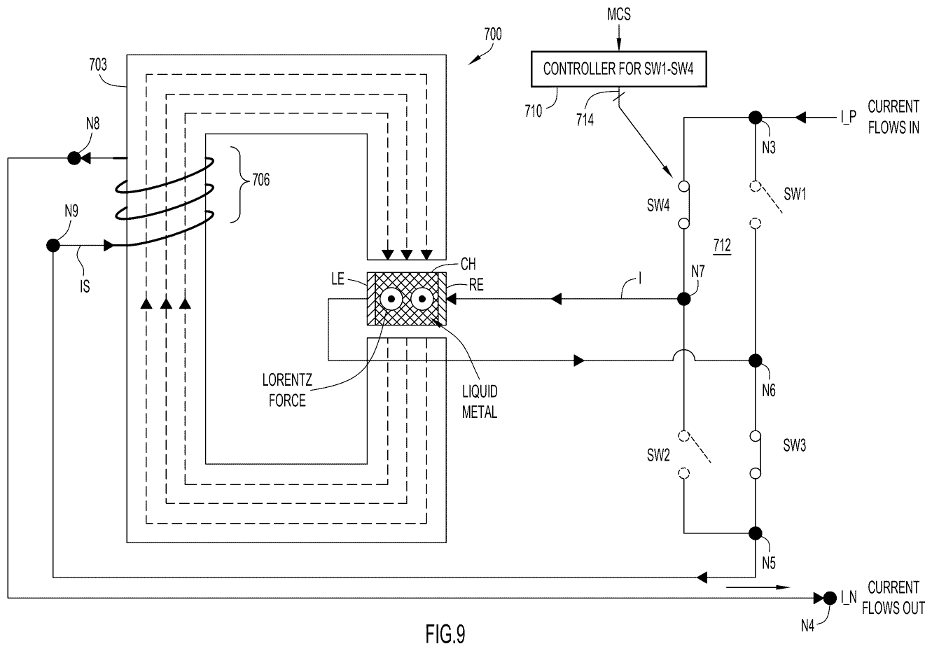

As will be described below in connection with FIGS. 8 and 9, responsive to the MCS indicating which mode is active, controller 710 can program PSN 712 into alternate power-switch configurations, including a mode 1 power-switch configuration (i.e., a first power-switch configuration), or a mode 2 power-switch configuration (i.e., a second power-switch configuration).

FIG. 8 shows MHD pump 700 for embodiment E2 operating in mode 1. In response to the MCS indicating mode, controller 710 asserts switch control signals 714 to program switches SW1-SW4 into the mode 1 power-switch configuration (i.e., the first power-switch configuration). Specifically, controller 710 asserts switch control signals 714 to close both SW1 and SW2 (i.e., to turn on both SW1 and SW2) and open both SW4 and SW3 (i.e., to turn off both SW3 and SW4). Responsive to the mode 1 power-switch configuration, a portion of current I_P (i.e., current I) flows to/across channel CH in the first current direction (e.g., left-to-right). The resulting Lorentz force pumps the liquid metal into the plane of the figure. Additionally, a portion of current I_P (i.e., winding current IS) flows into node N9 as winding current IS.

FIG. 9 shows MHD pump 700 for embodiment E2 operating in mode 2. In response to the MCS indicating mode 2, controller 710 asserts switch control signals 714 to program switches SW1-SW4 into the mode 2 power-switch configuration (i.e., the second power-switch configuration). Specifically, controller 710 asserts switch control signals 714 to open both SW1 and SW2 and close both SW3 and SW4. Responsive to the mode 2 power-switch configuration, a portion of current I_P (i.e., current I) flows to/across channel CH in the second current direction (e.g., right-to-left). The Lorentz force pumps the liquid metal out of the plane of the figure. Additionally, a portion of current I_P (i.e., winding current IS) flows into node N9. The different/alternate power-switch configurations for mode 1 and mode 2 only reverse the current direction of I applied to MHD pump 700, and thus the coolant-flow direction of the liquid metal in channel CH. In contrast, the alternate power-switch configurations maintain a constant current direction for winding current IS in field winding 706 relative to the reversing current directions of current I.

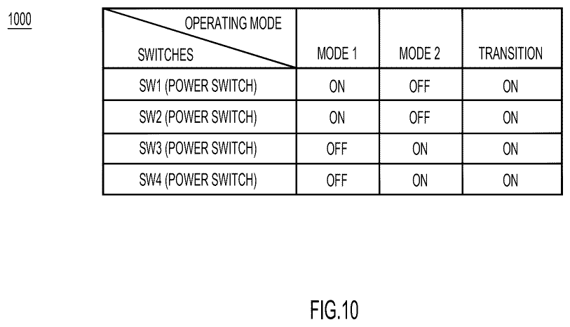

FIG. 10 is a table 1000 that shows mappings between operating modes mode 1, mode 2, and a transition mode and corresponding switch states (either on or off) for switches SW1-SW4. The information of table 1000 may be stored as a mode-switch mapping table in memory to be accessible to and used by the various controllers described herein (e.g., controller 105 and controller 710).

For embodiment E1, the reversal of current I applied to the MHD pump is automatic without any additional power switches. The all-on transition shown in table 1000 generates an overlap to make sure the current is always continuous. The transition time is related to the turn-on/turn-off time of the switches, where a shorter transition time can be used for fast switching devices such as power MOSFETs or power transistors.

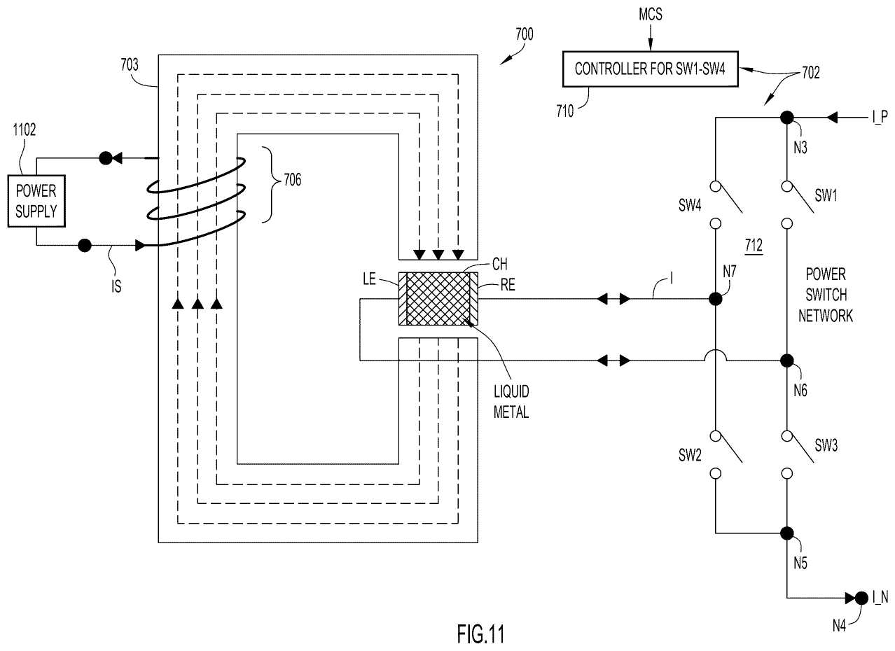

FIG. 11 is a diagram of variation of MHD pump 700 and current control circuit 702 for embodiment E2. The variation employs a separate power supply 1102 (in place of current control circuit 702) to supply field current IS to field winding 706. Separate power supply 1102 isolates a high inductance of field winding 706 from current I applied across the MHD current path.

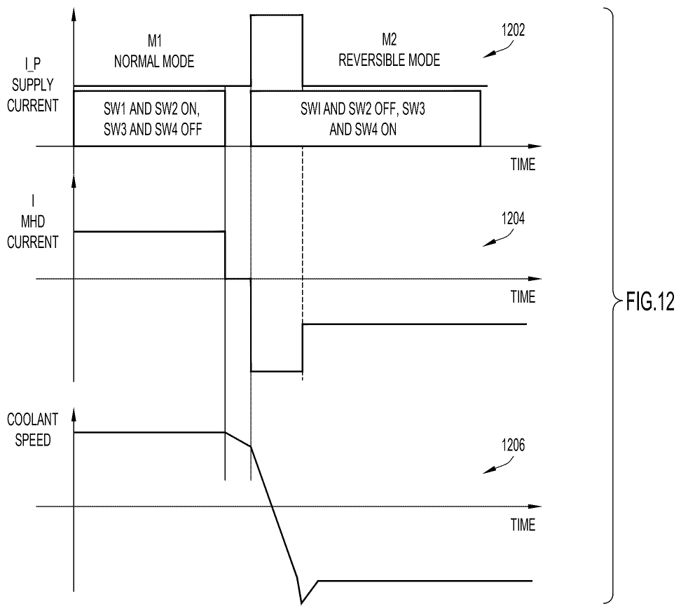

FIG. 12 shows waveforms 1202, 1204, and 1206 for supply current I_P, the MHD current I, and a speed of the liquid metal in channel CH for MHD pump 700 and current control circuit 702, for embodiment E2. The waveforms share a common time base. In FIG. 12, the “normal mode” and the “reversible mode” respectively correspond to mode 1 and mode 2.

Normally, the liquid metal has a high thermal conductivity. A high flow rate (i.e., speed) of the liquid metal may not be used in many applications. The liquid metal has a high viscosity, which helps stop a free running liquid metal flow. A current source with a programmable higher transient current I_P can be used to accelerate the reversal of the liquid metal flow.

FIG. 13 shows an example liquid metal coolant apparatus 1300 for embodiment M3 operating in mode 1 (e.g., power loss for Q1>Q2). Liquid metal coolant apparatus 1300 includes coolant loop A. Coolant loop A includes an MHD pump 1302 (e.g., according to embodiments E1 and E2), an L2AHE 1304 (referred to simply as a “heat exchanger 1304”), and cold plate 202 (thermally coupled with Q1 and Q2 as described above) all in fluid communication with each other via a contiguous conduit (as described above) to form coolant loop A. Coolant loop A carries the liquid metal through each of the foregoing components. A fan F may be used to cool heat exchanger 1304. A portion of coolant loop A (referred to as a “liquid metal path” of heat exchanger 1304 in FIG. 13) extends through and along a length of the heat exchanger between ports H1 and H2 (also referred to as “first and second ports”) of the heat exchanger positioned at opposing top and bottom ends of the heat exchanger. Liquid metal coolant loop A connects port H1 of heat exchanger 1304 to MHD pump 1302 (i.e., to channel CH), and also connects the MHD pump (i.e., channel CH) to port P1 of cold plate 202. Liquid metal coolant loop A also connects port P2 of cold plate 202 to port H2 of heat exchanger 1304.

In mode 1, MHD pump 1302 pumps cold liquid metal produced by heat exchanger 1304 at port H1 (referred to as a “cold port”) in the first coolant-flow direction (e.g., clockwise). Thus, the cold liquid metal flows from port H1 to port P1 through MHD pump 1302. MHD pump 1302 pumps the cold liquid metal from port P1 to port P2. As the cold liquid metal flows from port P1 to port P2, the cold liquid metal initially encounters and cools Q1, then encounters and cools Q2, and warms to become the hot liquid metal. The hot liquid metal exits port P2 and flows to port H2 (referred to as the “hot port”) of heat exchanger 1304. As the hot liquid metal flows from port H2 to H1 along the length of heat exchanger 1304 (i.e., along the liquid metal path of the heat exchanger), the heat exchanger cools the hot liquid metal to the cold liquid metal. Heat exchanger 1304 delivers the cold liquid metal to port H1, and the circular flow repeats.

FIG. 14 shows liquid metal coolant apparatus 1300 operating in mode 2 (e.g., power/heat loss for Q2>Q1). In mode 2, MHD pump 1302 pumps the cold liquid metal port H2 (the cold port) of heat exchanger 1304 in the second coolant-flow direction (e.g., counterclockwise). Thus, the cold liquid metal flows from port H2 to port P2. As the cold liquid metal flows from port P2 to port P1, the cold liquid metal initially encounters and cools Q2, then encounters and cools Q1, and warms to become the hot liquid metal. The hot liquid metal exits port P1 and flows to port H1 (the hot port) through MHD pump 1302. As the hot liquid metal flows from port H1 to H2 along the length of heat exchanger 1304, the heat exchanger cools the hot liquid metal, which becomes the cold liquid metal. The cold liquid metal exits port H2, and the circular flow repeats. Ports H1 and H2 reverse roles as the hot port and the cold port across modes 1 and 2.

FIG. 15 shows an example liquid metal coolant apparatus 1500 for embodiment M1 operating in mode 1 (e.g., power/heat loss for Q1>Q2). Liquid metal coolant apparatus 1500 employs an L2LHE 1501 (also referred to simply as a “heat exchanger 1501”). Liquid metal coolant apparatus 1500 implements two fluid loops that have respective flow directions that are synchronized across mode 1 and mode 2 to improve cooling of power circuit 104. The two fluid loops include (1) coolant loop A that circulates the liquid metal to cool power circuit 104 (as described above in connection with FIGS. 13 and 14), and (2) a cooling loop B (also referred to as a “liquid cooling loop”) that circulates a cooling liquid through heat exchanger 1501, to cool the heat exchanger and the liquid metal in the heat exchanger. The cooling liquid may include water (e.g., a non-liquid metal) or other liquid, for example. Liquid metal coolant apparatus 1500 synchronizes mode control with fluid flow directions in the two fluid loops A and B to ensure counterflow of the liquid metal coolant and the cooling liquid through two separate fluid paths of heat exchanger 1501 at all times.

To support the two fluid loops, heat exchanger 1501 incorporates the two separate fluid paths including (1) the liquid metal path (i.e. a coolant path) between ports H1 and H2 to convey the liquid metal as described above, and (2) a cooling liquid path CLP (shown in dashed line) to convey the cooling liquid through the heat exchanger to cool the heat exchanger and thus the liquid metal therein. The cooling liquid path CLP extends along the length of heat exchanger 1501 from a port H3 (adjacent to port H1) to a port H4 (adjacent to port H2) of the heat exchanger at opposing top and bottom ends of the heat exchanger. The cooling liquid flows through the cooling liquid path CLP of heat exchanger 1501 to cool heat exchanger 1501 while the liquid metal flows through the liquid metal path of the heat exchanger.

Liquid cooling loop B includes an inlet IN, an outlet OUT, heat exchanger 1501, and a conduit switch network CSN (also referred to as a “fluid switch network”) coupled to inlet IN, outlet OUT, and ports H3, H4 of the heat exchanger. Inlet In and outlet OUT represent an inlet to and an outlet from the CSN. A controller 1502 generates control signals 1503 to control/configure (e.g., program) the CSN into alternate conduits-switch configurations (e.g., a first conduit-switch configuration and a second conduit switch configuration) depending on the mode as indicated by the MCS. Inlet IN receives the cooling liquid from an external source (not shown) in a cold state. The cooling liquid in the cold state is referred to as a “cold cooling liquid.” Inlet IN injects the cold cooling liquid under pressure into cooling loop B. Outlet OUT receives the cooling liquid from the cooling loop in a warm state (referred to as a “hot cooling liquid”), and returns the same to the external source.

The CSN includes a network of “valved” conduits C1_{IN}, C1_{OUT}, C2_{IN}, and C2_{OUT} (collectively referred to as “conduits C”) connected between inlet IN, outlet OUT, port H3, and port H4 and configured to selectively connect inlet IN and outlet OUT to port H3 and port H4 through controllable fluid switches or valves K1_{IN}, K1_{OUT}, K2_{IN}, and K2_{OUT} (collectively referred to as “valves K”) coupled to respective ones of the conduits of the CSN. Valves K may be solenoid actuated valves, for example. Conduits C1_{IN} and C1_{OUT} may be referred to as first inlet and outlet conduits, and conduits C2_{IN} and C2_{OUT} may be referred to as second inlet and outlet conduits. Similarly, valves K1_{IN} and K1_{OUT} may be referred to as first inlet and outlet valves, and valves K2_{IN} and K2_{OUT} may be referred to as second inlet and outlet valves.

To configure the CSN, controller 1502 asserts control signals 1503(1), 1503(2) of control signals 1503 to open (i.e., turn on) and close (i.e., turn off) the valves depending on which mode is active (i.e., depending on the active mode of power circuit 104) to configure the network of conduits to deliver the cold liquid from inlet IN to port H3 or port H4, and to deliver the hot coolant from an alternative one of port H3 or port H4 to outlet OUT, which forms a reversible cooling loop that cools heat exchanger 1501. Controller 1502 controls valves K to reverse the direction of flow of the cold liquid through heat exchanger 1501 depending on the active mode. In this way, for modes 1 and 2, controller 1502 can place the CSN in the first and second conduit-switch configurations, as described below.

The CSN is now described in further detail. The CSN includes fluid connectors 1504, 1506, 1508, and 1510 (e.g., tee pipes, Y-connectors, or the like) that serve as fluid splitters or combiners (which may be bi-directional) for conduits C depending on a direction of flow. Fluid connector 1504 includes an input port 1504(1) coupled to inlet IN and to parallel output ports 1504(2), 1504(3) of the fluid connector. Fluid connector 1506 includes a combined output port 1506(1) coupled to outlet OUT and that is fed by parallel input ports 1506(2), 1506(3) of the fluid connector. Fluid connector 1508 includes an input/output port 1508(1) coupled to port H3 and to parallel output/input ports 1508(2), 1508(3) of the fluid connector. Fluid connector 1510 includes an input/output port 1510(1) coupled to port H4 and to parallel output/input ports 1510(2), 1510(3) of the fluid connector. Conduit C1_{IN} is coupled to ports 1504(2), 1508(2) through valve K1_{IN}, conduit C1_{OUT} is coupled to ports 1510(3), 1506(3) through valve K1_{OUT}, conduit C2_{IN} is coupled to ports 1504(3), 1510(2) through valve K2_{IN}, and conduit C2_{OUT} is coupled to ports 1508(3), 1506(2) through valve K2_{OUT}.

Valves K1_{IN} and K1_{OUT} are both controlled responsive to control signal 1503(1) of control signals 1503. Control signal 1503(1) has a first state/value and a second state/value that opens both valves to permit flow through the conduits and closes both valves to block the flow, respectively. Valves K2_{IN} and K2_{OUT} are both controlled responsive to control signal 1503(2) of control signals 1503. Control signal 1503(2) has a first state/value and a second state/value that opens both valves to permit flow through the conduits and closes both valves to block the flow, respectively.

As mentioned above, FIG. 15 shows operation of coolant loop A and cooling loop B in mode 1 (e.g., power/heat loss for Q1>Q2). In mode 1, current I controls MHD pump 1302 to pump the cold liquid metal through coolant loop A in the first coolant-flow direction (e.g., clockwise) to cool Q1 first and then Q2. With respect to heat exchanger 1501, the hot liquid metal enters port H2, flows from port H2 to port H1 (generally upward), and exits port H1.

Simultaneously, controller 1502 asserts control signals 1503 to place the CSN in the first conduit-switch configuration such that valves K1_{IN} and K1_{OUT} are turned on (i.e., closed), and valves K2_{IN} and K2_{OUT} are turned off (i.e., open), to circulate the cooling liquid through cooling loop B in a first cooling-liquid flow direction (e.g., clockwise). The cold cooling liquid flows from inlet IN to port H3, to port H4, and then to outlet OUT. With respect to heat exchanger 1501, the cold cooling liquid enters port H3, flows from port H3 to port H4 (generally downward), and exits port H4 as the hot cooling liquid. Thus, in mode 1, the hot liquid metal and the cold cooling liquid circulate through heat exchanger 1501 in counterflow directions (e.g., counter-rotating directions). That is, the mode 1 configurations of coolant loop A and liquid coolant loop B maintain a counterflow (i.e., opposite flow direction) of the cold liquid metal and the hot cooling liquid at/through heat exchanger 1501.

FIG. 16 shows liquid metal coolant apparatus 1500 for embodiment M1 operating in mode 2 (e.g., power/heat loss for Q2>Q1). Controller 1502 is omitted for illustrative convenience. In mode 2, current I controls MHD pump 1302 to pump the cold liquid metal through coolant loop A in the second coolant-flow direction (e.g., counterclockwise) to cool Q2 first and then Q1. With respect to heat exchanger 1501, the hot liquid metal enters port H1, flows from port H1 to port H2 (generally downward), and exits port H2 as the cold liquid metal.

Simultaneously, controller 1502 asserts control signals 1503 to place the CSN in the second conduit-switch configuration such that valves K1_{IN} and K1_{OUT} are turned off, and valves K2_{IN} and K2_{OUT} are turned on, to circulate the cold cooling liquid through cooling loop B in a second cooling-liquid flow direction (e.g., counterclockwise). The cold cooling liquid flows from inlet IN to port H4, to port H3, and then to outlet OUT as the hot cooling liquid. With respect to heat exchanger 1501, the cold cooling liquid enters port H4, flows from port H4 to port H3 (generally upward), and exits port H3 as the hot cooling liquid. Thus, in mode 2, the hot liquid metal and the cold cooling liquid circulate through heat exchanger 1501 in counterflow directions. That is, the mode 2 configurations of coolant loop A and liquid coolant loop B maintain a counterflow of the hot liquid metal and the cold cooling liquid at heat exchanger 1501.

FIG. 17 shows another example liquid metal coolant apparatus 1700 for embodiment M2 operating in mode 1 (e.g., power/heat loss for Q1>Q2). Liquid metal coolant apparatus 1700 employs heat exchanger 1501. A difference between liquid metal coolant apparatus 1700 and liquid metal coolant apparatus 1500 is that the CSN is moved from the cooling loop to the coolant loop. Liquid metal coolant apparatus 1700 includes a coolant loop C and a cooling loop D. Liquid cooling loop D connects inlet IN, outlet OUT directly to ports H3, H4 of heat exchanger 1501. Thus, cold cooling liquid from inlet IN enters port H3, flows from port H3 to port H4 (generally downward), and then flows to outlet OUT, always.

Liquid metal coolant loop C includes heat exchanger 1501, the CSN, MHD pump 1302, and cold plate 202. Liquid metal coolant loop C connects port H1 of heat exchanger 1501 to port 1504(1) of the CSN, port 1508(1) of the CSN to MHD pump 1302 (e.g., channel CH), the MHD pump (e.g., channel CH) to port P1 of cold plate 202, port P2 of the cold plate to port 1510(1) of the CSN, and port 1506(1) of the CSN to port H2 of the heat exchanger.

In mode 1, current I controls MHD pump 1302 to pump the liquid metal through coolant loop C in the first coolant-flow direction (e.g., clockwise). Simultaneously, controller 1502 asserts control signals 1503 to place the CSN in the first conduit-switch configuration such that valves K1_{IN} and K1_{OUT} are turned on, and valves K2IN and K2OUT are turned off. Thus, the cold liquid metal that exits port H1 of heat exchanger 1501 flows through the CSN and MHD pump 1302 to port P1 of cold plate 202 to cool Q1 first, and then flows to port P1 of the cold plate to cool Q2, and warms to the hot liquid metal. The hot liquid metal flows from port P2 of cold plate 202 to port H2 of heat exchanger 1501 through the CSN, and then flows from port H2 to port H1 (generally upward), to cool to the cold liquid metal. The cold liquid metal exits port H2 and repeats the circuit. Thus, the mode 1 configurations of coolant loop C and liquid cooling loop D maintain a counterflow of the liquid metal and the cooling liquid at heat exchanger 1501.

FIG. 18 shows liquid metal coolant apparatus 1700 for embodiment M2 operating in mode 2 (e.g., power/heat loss for Q2>Q1). In mode 2, current I controls MHD pump 1302 to pump the liquid metal through coolant loop C in the second coolant-flow direction (e.g., counterclockwise). Simultaneously, controller 1502 asserts control signals 1503 to place the CSN in the second conduit-switch configuration such that valves K1_{IN} and K1_{OUT} are turned off, and valves K2_{IN} and K2_{OUT} are turned on. Thus, the cold liquid metal that exits port H1 of heat exchanger 1501 flows through the CSN directly to port P2 of cold plate 202 to cool Q2 first, and then flows to port P1 of the cold plate to cool Q1, and warms to the hot liquid metal. The hot liquid metal flows from port P1 of cold plate 202 to port H2 of heat exchanger 1501 through MHD pump 1302 and the CSN, and then flows from port H2 to port H1 (generally upward), and cools to the cold liquid metal. The cold liquid metal exits port H1 and repeats the circuit. Thus, the mode 2 configurations of coolant loop C and liquid cooling loop D maintain a counterflow of the liquid metal and the cooling liquid at heat exchanger 1501.

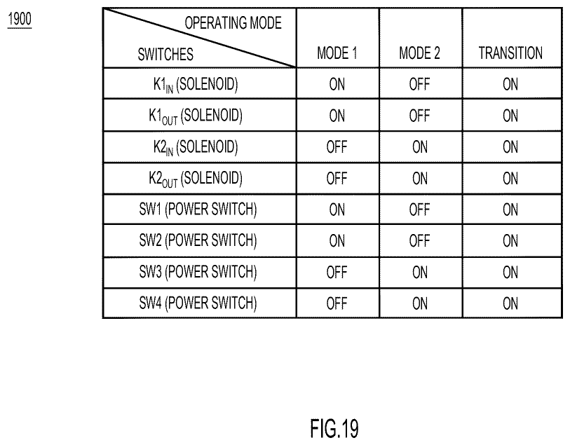

FIG. 19 is a table 1900 that shows mappings between operating modes 1 and 2, a transition mode, and corresponding switch states for switches SW1-SW4 and the valves. The information of tables 1000 and 1900 may be stored as mode-switch and fluid-valve mapping tables in memory to be accessible to and used by the various controllers described herein (e.g., controller 105, controller 710, and controller 1502).

FIG. 20 is a flowchart on an example method 2000 of cooling an electric circuit (e.g., power circuit 104) using an MHD pump that circulates liquid metal through a coolant loop.

2002 includes providing electric circuits including a first circuit and a second circuit configured to operate in multiple (e.g., reversible) modes including a first mode in which the first circuit dissipates more heat than the second circuit and in a second mode in which the second circuit dissipates more heat than the first circuit.

2004 includes providing a coolant loop along which the first circuit and the second circuit are thermally coupled at spaced-apart locations, wherein the coolant loop includes a reversible magnetohydrodynamic (MHD) pump. The coolant loop includes a conduit segment (e.g., integrated with cold plate 202) having spaced-apart first and second (open) ends (e.g., ports P1 and P2 of the cold plate 202) adjacent to the first circuit and the second circuit.

2006 includes, by the MHD pump, pumping a cold liquid metal through the coolant loop (and thus through the conduit segment) in reversible coolant-flow directions responsive to reversible current directions of a current applied to the MHD pump, such that when the first mode is active, the cold liquid metal initially encounters the first circuit that dissipates more heat and then encounters the second circuit, and when the second mode is active, the cold liquid metal initially encounters the second circuit that dissipates more heat and then encounters the first circuit.

The electric circuits are configured to warm the cold liquid metal to a hot liquid metal as the cold liquid metal encounters the electric circuits. The coolant loop includes a heat exchanger to receive the hot liquid metal, cool the hot liquid metal to the cold liquid metal, and return the cold liquid metal. The heat exchanger includes a first port and a second port coupled to the first end and the second end of the conduit segment to support circulation of the liquid metal through the coolant loop.

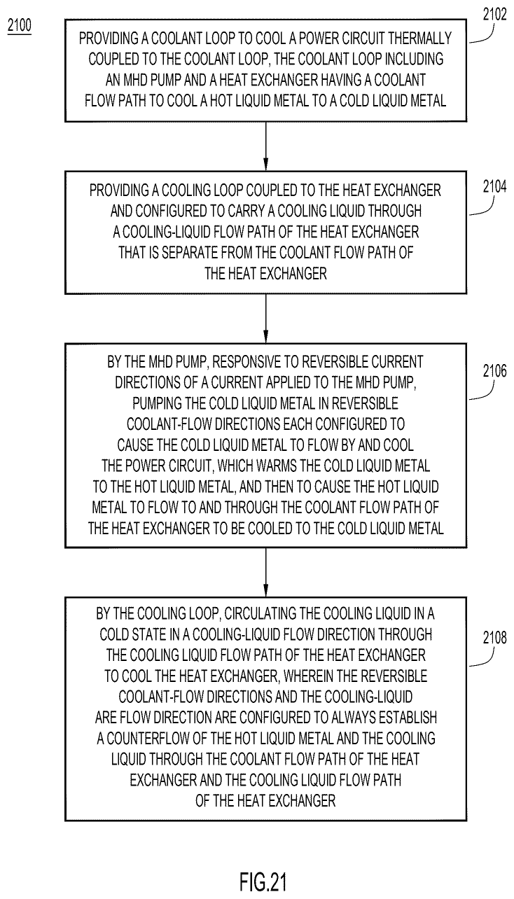

FIG. 21 is a flowchart on an example method 2100 of cooling an electric circuit (e.g., power circuit 104) using multiple flow loops.

2102 includes providing a coolant loop to cool a power circuit thermally coupled to the coolant loop, the coolant loop including an MHD pump and a heat exchanger having a coolant flow path to cool a hot liquid metal to a cold liquid metal.

2104 includes providing a cooling loop coupled to the heat exchanger and configured to carry a cooling liquid through a cooling-liquid flow path of the heat exchanger that is separate from the coolant flow path of the heat exchanger.

2106 includes, by the MHD pump, responsive to reversible current directions of a current applied to the MHD pump, pumping the cold liquid metal in reversible coolant-flow directions each configured to cause the cold liquid metal to flow by and cool the power circuit, which warms the cold liquid metal to the hot liquid metal, and then to cause the hot liquid metal to flow to and through the coolant flow path of the heat exchanger to be cooled thereby to the cold liquid metal.

2108 includes, by the cooling loop, circulating the cooling liquid in a cold state in a cooling-liquid flow direction through the cooling liquid flow path of the heat exchanger to cool the heat exchanger, wherein the reversible coolant-flow directions and the cooling-liquid flow direction are configured to always establish a counterflow of the hot liquid metal and the cooling liquid through the heat exchanger.

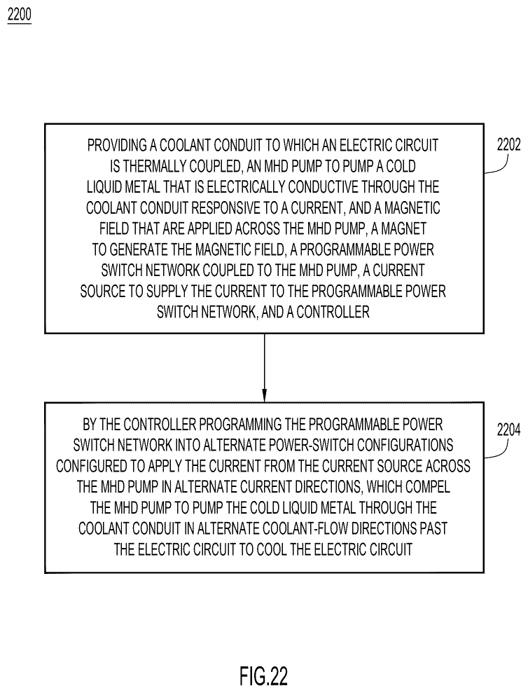

FIG. 22 is a flowchart on an example method 2200 of operating an MHD pump.

At 2202, providing a coolant conduit to which an electric circuit is thermally coupled, an MHD pump to pump a cold liquid metal that is electrically conductive through the coolant conduit responsive to a current and a magnetic field that are applied across the MHD pump, a magnet to generate the magnetic field, a programmable power switch network coupled to the MHD pump, a current source to supply the current to the programmable power switch network, and a controller.

At 2204, by the controller, programming the programmable power switch network into alternate power-switch configurations configured to apply the current from the current source across the MHD pump in alternate current directions, which compel the MHD pump to pump the cold liquid metal through the coolant conduit in alternate coolant-flow directions past the electric circuit to cool the electric circuit.

In summary, the embodiments include, but are not limited to, methods to improve the cooling of a bi-directional non-isolated DC/DC converter with a first circuit and a second circuit, which is separated from the first circuit, using a reversible MHD pump to pump a cold liquid metal to initially encounter/flow by whichever circuit dissipates more heat, and then to encounter the other circuit. Four embodiments M1, M2, E1, and E2 may be used with an L2LHE. Two embodiments may use an L2AHE.

The embodiments include a control method to change current flow directions to change the direction of the Lorentz force naturally (e.g., in embodiments E1) or to change the direction of the Lorentz force programmatically using four switches SW-SW4 (e.g., in embodiment E2).

The embodiments include a method to reduce the transient time of a mode change, as in the variation of embodiment E2 (e.g., with either a separate field winding power supply or with a PM).

The embodiments include a method to maintain a high cooling efficiency in the L2LHE by changing the direction of the cooling liquid to the heat exchanger (e.g., embodiment M1).

The embodiments include a method to maintain a high cooling efficiency in the L2LHE by changing the direction of coolant in the heat exchanger (e.g., embodiment M2).

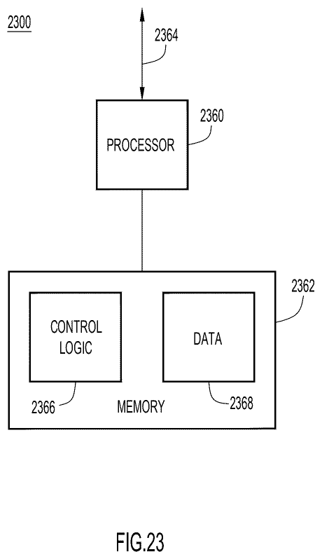

FIG. 23 is a block diagram of an example controller 2300 configured to perform operations described herein. Controller 2300 may represent controllers 105, 710, and 1502 individually when the controllers are separate controllers, or collectively when the controllers are integrated into a single controller, for example. Controller 2300 includes processor(s) 2360 and a memory 2362 coupled to one another. The aforementioned components may be implemented in hardware (e.g., a hardware processor), software (e.g., a software processor), or a combination thereof. Processor(s) 2360 communicate with other entities/processes over hardware and/or software interfaces 2364, e.g., to provide switching signals 108 to switching transistors Q1, Q2, switch control signals 714 to switches SW1-SW4, and control signals 1503 to valves, to provide the MCS, and to communicate with other processors, for example.

Memory 2362 stores control software 2366 (referred as “control logic”), that when executed by the processor(s) 2360, causes the processor(s), and more generally, controller 2300, to perform the various operations described herein. The processor(s) 2360 may be a microprocessor or microcontroller (or multiple instances of such components). The memory 2362 may include read only memory (ROM), random access memory (RAM), magnetic disk storage media devices, optical storage media devices, flash memory devices, electrical, optical, or other physically tangible (i.e., non-transitory) memory storage devices. Controller 2300 may also be discrete logic embedded within an integrated circuit (IC) device.

Thus, in general, the memory 2362 may comprise one or more tangible (non-transitory) computer readable storage media (e.g., memory device(s)) including a first non-transitory computer readable storage medium, a second non-transitory computer readable storage medium, and so on, encoded with software or firmware that comprises computer executable instructions. For example, control software 2366 includes logic to implement operations performed by the controller 2300. Thus, control software 2366 implements the various methods/operations described herein.

In addition, memory 2362 stores data 2368 used and produced by control software 2366.

In some aspects, the techniques described herein relate to an apparatus including: electric circuits including a first circuit and a second circuit configured to operate in multiple modes including a first mode in which the first circuit dissipates more heat than the second circuit and in a second mode in which the second circuit dissipates more heat than the first circuit; and a coolant loop along which the first circuit and the second circuit are thermally coupled at spaced-apart locations, wherein the coolant loop includes a reversible magnetohydrodynamic (MHD) pump to pump a cold liquid metal through the coolant loop in reversible coolant-flow directions responsive to reversible current directions of a current applied to the MHD pump, such that when the first mode is active, the cold liquid metal initially encounters the first circuit and then encounters the second circuit, and when the second mode is active, the cold liquid metal initially encounters the second circuit and then encounters the first circuit.

In some aspects, the techniques described herein relate to an apparatus, wherein the MHD pump is configured to: responsive to a first current direction of the current when the first mode is active, pump the cold liquid metal in a first coolant-flow direction to cause the cold liquid metal to initially encounter the first circuit; and responsive to a second current direction of the current when the second mode is active, pump the cold liquid metal in a second coolant-flow direction to cause the cold liquid metal to initially encounter the second circuit and then encounter the first circuit.

In some aspects, the techniques described herein relate to an apparatus, further including: a current source to supply the current to the MHD pump in the first current direction when the first mode is active and in the second current direction when the second mode is active.

In some aspects, the techniques described herein relate to an apparatus, wherein the electric circuits serve as the current source to supply the current to the MHD pump in the first current direction and the second current direction when the first mode is active and the second mode is active, respectively.

In some aspects, the techniques described herein relate to an apparatus, wherein the MHD pump is configured to: increase and decrease a flow rate of the cold liquid metal in correspondence with an increase and a decrease in a level of the current, respectively.

In some aspects, the techniques described herein relate to an apparatus, wherein: the electric circuits are configured to warm the cold liquid metal to a hot liquid metal as the cold liquid metal encounters the electric circuits; and the coolant loop includes a heat exchanger to receive the hot liquid metal, cool the hot liquid metal to the cold liquid metal, and return the cold liquid metal.

In some aspects, the techniques described herein relate to an apparatus, wherein: the coolant loop includes a conduit segment having a first end and a second end to which the first circuit and the second circuit are thermally coupled, respectively; the heat exchanger includes a first port and a second port coupled to the first end and the second end of the conduit segment; in the first mode, the first port and the second port serve as a cold port and a hot port to supply the cold liquid metal to the first end and to receive the hot liquid metal from the second end, respectively; and in the second mode, the first port and the second port have reverse roles to serve as the hot port and the cold port, respectively.

In some aspects, the techniques described herein relate to an apparatus, wherein: the coolant loop further includes a conduit switch network coupled to the heat exchanger and configured to be programmed into alternate conduit-switch configurations corresponding to whichever of the multiple modes is active to direct the cold liquid metal to whichever of the electric circuits dissipates more heat.

In some aspects, the techniques described herein relate to an apparatus, wherein: the coolant loop includes a conduit segment having a first end and a second end to which the first circuit and the second circuit are thermally coupled, respectively; and the alternate conduit-switch configurations of the conduit switch network include: a first conduit-switch configuration when the first mode is active to direct the cold liquid metal from a cold port of the heat exchanger to the first end; and a second conduit-switch configuration when the second mode is active to direct the cold liquid metal from the cold port to the second end.

In some aspects, the techniques described herein relate to an apparatus including: a coolant loop to cool a power circuit thermally coupled to the coolant loop, the coolant loop including a heat exchanger to cool a hot liquid metal to a cold liquid metal, and a magnetohydrodynamic (MHD) pump, responsive to reversible current directions of a current applied to the MHD pump, to pump the cold liquid metal in reversible coolant-flow directions each configured to cause the cold liquid metal to flow by and cool the power circuit, which warms the cold liquid metal to the hot liquid metal, and then to cause the hot liquid metal to flow to the heat exchanger; and a cooling loop to circulate a cooling liquid in a cooling-liquid flow direction through the heat exchanger to cool the hot liquid metal in the heat exchanger, wherein the reversible coolant-flow directions and the cooling-liquid flow direction are configured to establish a counterflow of the hot liquid metal and the cooling liquid through the heat exchanger.

In some aspects, the techniques described herein relate to an apparatus, wherein: the power circuit includes a first circuit and a second circuit thermally coupled to the coolant loop at spaced-apart locations along the coolant loop; the reversible current directions include a first current direction and a second current direction; and the reversible coolant-flow directions include a first coolant-flow direction to cause the cold liquid metal to initially encounter the first circuit and then encounter the second circuit, and a second coolant-flow direction to cause the cold liquid metal to initially encounter the second circuit and then encounter the first circuit.

In some aspects, the techniques described herein relate to an apparatus, wherein the power circuit is configured to operate in multiple modes that include: a first mode in which the current flows in the first current direction through the first circuit and the second circuit and in which the first circuit dissipates more heat than the second circuit; and a second mode in which the current flows in the second current direction through the first circuit and the second circuit and in which the second circuit dissipates more heat than the first circuit.

In some aspects, the techniques described herein relate to an apparatus, wherein the cooling loop includes: an inlet to receive the cooling liquid, and an outlet to which the cooling liquid is returned; and a conduit switch network coupled to the inlet, the outlet, and the heat exchanger, wherein the conduit switch network is configured to circulate the cooling liquid from the inlet to the outlet and through the heat exchanger in reversible cooling-liquid flow directions that are synchronized to the reversible coolant-flow directions so as to maintain the counterflow through the heat exchanger.

In some aspects, the techniques described herein relate to an apparatus, wherein the conduit switch network includes: a network of conduits and fluid valves configured to selectively connect the inlet and the outlet to a first port and a second port of the heat exchanger between which the cooling liquid flows.

In some aspects, the techniques described herein relate to an apparatus, wherein the network of the conduits and the fluid valves have selectable configurations including: a first configuration to connect the inlet to the first port and the second port to the outlet to circulate the cooling liquid in a first cooling-liquid flow direction through the heat exchanger; and a second configuration to connect the inlet to the second port and the first port to the outlet, to circulate the cooling liquid in a second cooling-liquid flow direction through the heat exchanger.

In some aspects, the techniques described herein relate to an apparatus, wherein: the power circuit includes a first circuit and a second circuit thermally coupled to the coolant loop at spaced-apart locations along the coolant loop; and the coolant loop includes a conduit switch network having a first configuration corresponding to a first coolant-flow direction of the reversible coolant-flow directions to cause the cold liquid metal to initially encounter the first circuit and then encounter the second circuit, and a second configuration corresponding to a second coolant-flow direction of the reversible coolant-flow directions to cause the cold liquid metal to initially encounter the second circuit and then encounter the first circuit.

In some aspects, the techniques described herein relate to an apparatus, wherein: the heat exchanger includes a cold port to supply the cold liquid metal and a hot port to receive the hot liquid metal; the cooling loop includes a first port adjacent to the first circuit and a second port adjacent to the second circuit; the first configuration of the conduit switch network is configured to connect the cold port to the first port and the hot port to the second port; and the second configuration of the conduit switch network is configured to connect the cold port to the second port and the hot port to the first port.

In some aspects, the techniques described herein relate to an apparatus including: a coolant conduit to which an electric circuit is thermally coupled; a magnetohydrodynamic (MHD) pump to pump a cold liquid metal that is electrically conductive through the coolant conduit responsive to a current and a magnetic field that are applied across the MHD pump; a magnet to generate the magnetic field; a programmable power switch network coupled to the MHD pump; a current source to supply the current to the programmable power switch network; and a controller to program the programmable power switch network into alternate power-switch configurations configured to apply the current from the current source across the MHD pump in alternate current directions, which compel the MHD pump to pump the cold liquid metal through the coolant conduit in alternate coolant-flow directions past the electric circuit to cool the electric circuit.

In some aspects, the techniques described herein relate to an apparatus, wherein: the alternate power-switch configurations include a first power-switch configuration and a second power-switch configuration configured to apply the current to the MHD pump in a first current direction and a second current direction to compel the MHD pump to pump the cold liquid metal through the coolant conduit in a first coolant-flow direction and a second coolant-flow direction past the electric circuit, respectively.

In some aspects, the techniques described herein relate to an apparatus, wherein the programmable power switch network includes: an input node to receive the current and a return node to return the current; and multiple switches connected to the input node, the return node, a first electrode of the MHD pump, and a second electrode of the MHD pump, the multiple switches configured to be programmed responsive to control signals generated by the controller.

In some aspects, the techniques described herein relate to an apparatus, wherein: in the first power-switch configuration, the multiple switches are configured to connect the input node to the first electrode and connect the return node to the second electrode; and in the second power-switch configuration, the multiple switches are configured to connect the input node to the second electrode and connect the return node to the first electrode.

In some aspects, the techniques described herein relate to an apparatus, wherein the multiple switches include: a first switch and a second switch connected in series with each other from the input node to the return node, and to each other at a first intermediate node that is connected to the first electrode; and a third switch and a fourth switch connected in series with each other from the input node to the return node, and to each other at a second intermediate node that is connected to the second electrode of the MHD pump.

In some aspects, the techniques described herein relate to an apparatus, further including: a winding current source to generate a winding current, wherein the magnet includes an electromagnet that includes a winding to carry the winding current to induce the magnetic field.

In some aspects, the techniques described herein relate to an apparatus, wherein: the programmable power switch network serves as the winding current source, such that the alternate power-switch configurations are configured to apply the current to the winding in a winding current direction that is constant with respect to the alternate current directions applied to the MHD pump.

In some aspects, the techniques described herein relate to an apparatus, wherein: the electric circuit includes a first circuit and a second circuit that are spaced-apart along the coolant conduit and are configured to operate in a first mode in which the first circuit dissipates more heat than the second circuit and in a second mode in which the second circuit dissipates the more heat; and the alternate current directions are configured to cause the cold liquid metal to flow initially to whichever of the first circuit and the second circuit dissipates the more heat in whichever mode is active, and then to whichever of the first circuit and the second circuit does not dissipate the more heat.

The above description is intended by way of example only. Although the techniques are illustrated and described herein as embodied in one or more specific examples, it is nevertheless not intended to be limited to the details shown, since various modifications and structural changes may be made within the scope and range of equivalents of the claims.

What is claimed is:

1. An apparatus comprising:
electric circuits including a first circuit and a second circuit configured to operate in multiple modes including a first mode in which the first circuit dissipates more heat than the second circuit and in a second mode in which the second circuit dissipates more heat than the first circuit; and
a coolant loop along which the first circuit and the second circuit are thermally coupled at spaced-apart locations, wherein the coolant loop includes a reversible magnetohydrodynamic (MHD) pump to pump a cold liquid metal through the coolant loop in reversible coolant-flow directions responsive to reversible current directions of a current applied to the MHD pump, such that when the first mode is active, the cold liquid metal initially encounters the first circuit and then encounters the second circuit, and when the second mode is active, the cold liquid metal initially encounters the second circuit and then encounters the first circuit.

2. The apparatus of claim 1, wherein the MHD pump is configured to:
responsive to a first current direction of the current when the first mode is active, pump the cold liquid metal in a first coolant-flow direction to cause the cold liquid metal to initially encounter the first circuit; and
responsive to a second current direction of the current when the second mode is active, pump the cold liquid metal in a second coolant-flow direction to cause the cold liquid metal to initially encounter the second circuit and then encounter the first circuit.

3. The apparatus of claim 2, further comprising:
a current source to supply the current to the MHD pump in the first current direction when the first mode is active and in the second current direction when the second mode is active.

4. The apparatus of claim 3, wherein the electric circuits serve as the current source to supply the current to the MHD pump in the first current direction and the second current direction when the first mode is active and the second mode is active, respectively.

5. The apparatus of claim 4, wherein the MHD pump is configured to:
increase and decrease a flow rate of the cold liquid metal in correspondence with an increase and a decrease in a level of the current, respectively.

6. The apparatus of claim 1, wherein:
the electric circuits are configured to warm the cold liquid metal to a hot liquid metal as the cold liquid metal encounters the electric circuits; and
the coolant loop includes a heat exchanger to receive the hot liquid metal, cool the hot liquid metal to the cold liquid metal, and return the cold liquid metal.

7. The apparatus of claim 6, wherein:
the coolant loop includes a conduit segment having a first end and a second end to which the first circuit and the second circuit are thermally coupled, respectively;
the heat exchanger includes a first port and a second port coupled to the first end and the second end of the conduit segment;
in the first mode, the first port and the second port serve as a cold port and a hot port to supply the cold liquid metal to the first end and to receive the hot liquid metal from the second end, respectively; and
in the second mode, the first port and the second port have reverse roles to serve as the hot port and the cold port, respectively.

8. The apparatus of claim 6, wherein:
the coolant loop further includes a conduit switch network coupled to the heat exchanger and configured to be programmed into alternate conduit-switch configurations corresponding to whichever of the multiple modes is active to direct the cold liquid metal to whichever of the electric circuits dissipates more heat.

9. An apparatus comprising:
a coolant loop to cool a power circuit thermally coupled to the coolant loop, the coolant loop including a heat exchanger to cool a hot liquid metal to a cold liquid metal, and a magnetohydrodynamic (MHD) pump, responsive to reversible current directions of a current applied to the MHD pump, to pump the cold liquid metal in reversible coolant-flow directions each configured to cause the cold liquid metal to flow by and cool the power circuit, which warms the cold liquid metal to the hot liquid metal, and then to cause the hot liquid metal to flow to the heat exchanger; and
a cooling loop to circulate a cooling liquid in a cooling-liquid flow direction through the heat exchanger to cool the hot liquid metal in the heat exchanger, wherein the reversible coolant-flow directions and the cooling-liquid flow direction are configured to establish a counterflow of the hot liquid metal and the cooling liquid through the heat exchanger.

10. The apparatus of claim 9, wherein:
the power circuit includes a first circuit and a second circuit thermally coupled to the coolant loop at spaced-apart locations along the coolant loop;
the reversible current directions include a first current direction and a second current direction; and
the reversible coolant-flow directions include a first coolant-flow direction to cause the cold liquid metal to initially encounter the first circuit and then encounter the second circuit, and a second coolant-flow direction to cause the cold liquid metal to initially encounter the second circuit and then encounter the first circuit.

11. The apparatus of claim 10, wherein the power circuit is configured to operate in multiple modes that include:
a first mode in which the current flows in the first current direction through the first circuit and the second circuit and in which the first circuit dissipates more heat than the second circuit; and
a second mode in which the current flows in the second current direction through the first circuit and the second circuit and in which the second circuit dissipates more heat than the first circuit.

12. The apparatus of claim 9, wherein the cooling loop includes:
an inlet to receive the cooling liquid, and an outlet to which the cooling liquid is returned; and
a conduit switch network coupled to the inlet, the outlet, and the heat exchanger, wherein the conduit switch network is configured to circulate the cooling liquid from the inlet to the outlet and through the heat exchanger in reversible cooling-liquid flow directions that are synchronized to the reversible coolant-flow directions so as to maintain the counterflow through the heat exchanger.

13. The apparatus of claim 12, wherein the conduit switch network includes:
a network of conduits and fluid valves configured to selectively connect the inlet and the outlet to a first port and a second port of the heat exchanger between which the cooling liquid flows.

14. The apparatus of claim 13, wherein the network of the conduits and the fluid valves have selectable configurations including:
a first configuration to connect the inlet to the first port and the second port to the outlet to circulate the cooling liquid in a first cooling-liquid flow direction through the heat exchanger; and
a second configuration to connect the inlet to the second port and the first port to the outlet, to circulate the cooling liquid in a second cooling-liquid flow direction through the heat exchanger.

15. The apparatus of claim 9, wherein:
the power circuit includes a first circuit and a second circuit thermally coupled to the coolant loop at spaced-apart locations along the coolant loop; and
the coolant loop includes a conduit switch network having a first configuration corresponding to a first coolant-flow direction of the reversible coolant-flow directions to cause the cold liquid metal to initially encounter the first circuit and then encounter the second circuit, and a second configuration corresponding to a second coolant-flow direction of the reversible coolant-flow directions to cause the cold liquid metal to initially encounter the second circuit and then encounter the first circuit.

16. An apparatus comprising:
a coolant conduit to which an electric circuit is thermally coupled;
a magnetohydrodynamic (MHD) pump to pump a cold liquid metal that is electrically conductive through the coolant conduit responsive to a current and a magnetic field that are applied across the MHD pump;
a magnet to generate the magnetic field;
a programmable power switch network coupled to the MHD pump;
a current source to supply the current to the programmable power switch network; and
a controller to program the programmable power switch network into alternate power-switch configurations configured to apply the current from the current source across the MHD pump in alternate current directions, which compel the MHD pump to pump the cold liquid metal through the coolant conduit in alternate coolant-flow directions past the electric circuit to cool the electric circuit.

17. The apparatus of claim 16, wherein:
the alternate power-switch configurations include a first power-switch configuration and a second power-switch configuration configured to apply the current to the MHD pump in a first current direction and a second current direction to compel the MHD pump to pump the cold liquid metal through the coolant conduit in a first coolant-flow direction and a second coolant-flow direction past the electric circuit, respectively.

18. The apparatus of claim 17, wherein the programmable power switch network includes:
an input node to receive the current and a return node to return the current; and
multiple switches connected to the input node, the return node, a first electrode of the MHD pump, and a second electrode of the MHD pump, the multiple switches configured to be programmed responsive to control signals generated by the controller.

19. The apparatus of claim 18, wherein:
in the first power-switch configuration, the multiple switches are configured to connect the input node to the first electrode and connect the return node to the second electrode; and
in the second power-switch configuration, the multiple switches are configured to connect the input node to the second electrode and connect the return node to the first electrode.

20. The apparatus of claim 16, further comprising:
a winding current source to generate a winding current,
wherein the magnet includes an electromagnet that includes a winding to carry the winding current to induce the magnetic field.
